(19) United States
(12) Patent Application Publication
(10) Pub. No.: US 2025/0362558 A1
(43) Pub. Date: Nov. 27, 2025

(54) PIEZOELECTRIC OPTICAL ELEMENT AND SYSTEM

(71) Applicant: Kureha America, Inc., Houston, TX (US)

(72) Inventors: Mayu Komatsu, Houston, TX (US); Tatsuya Yaguchi, Houston, TX (US); Syed Muhammad Mohsin Jafri, Houston, TX (US); Wei Li, Houston, TX (US); Hiroaki Yoshida, Houston, TX (US)

(73) Assignee: Kureha America, Inc., Houston, TX (US)

(21) Appl. No.: 18/874,816

(22) PCT Filed: Jun. 12, 2023
(86) PCT No.: PCT/US2023/025027

§ 371 Date: Dec. 13, 2024

Related U.S. Application Data
(60) Provisional application No. 63/352,199, filed on Jun. 14, 2022.
(60) Provisional application No. 63/406,613, filed on Sep. 14, 2022.

(51) Int. Cl. G02F 1/29; G02B 3/14; G02B 26/08; G02B 27/00; G02B 27/01; H10N 30/20; H10N 30/857

(52) U.S. Cl. CPC G02F 1/294; G02B 3/14; G02B 26/0875; G02B 27/005; G02B 27/0093; G02B 27/0172; G02B 27/0179; H10N 30/206; H10N 30/857; G02B 2027/0187

(57) ABSTRACT

An optical element includes a first piezoelectric layer of fluorinated polymer with a piezoelectric coefficient, d₃₁, of at least 25 pC/N and an electrode layer disposed on the first piezoelectric layer. An optical characteristic of the optical element changes when the first piezoelectric layer is deformed upon application of a voltage at the electrode layer.

### CROSS-REFERENCE TO RELATED APPLICATIONS

This application claims the benefit of priority under 35 U.S.C. § 119(e) to U.S. Provisional Patent Application Ser. No. 63/352,199, filed on Jun. 14, 2022, which is hereby incorporated by reference herein in its entirety. This application further claims the benefit of priority under 35 U.S.C. § 119(e) to U.S. Provisional Patent Application Ser. No. 63/406,613, filed on Sep. 14, 2022, which is hereby incorporated by reference herein in its entirety.

### BACKGROUND

Optical elements such as lenses, mirrors, etc. may be used to focus or disperse a light beam. The optical behavior of an optical element may be affected by the geometry of the optical element. For example, a spherical lens has optical characteristics different from a concave optical lens. Accordingly, adjustment of the geometry of a non-rigid optical element may alter the optical characteristics of the optical element. Piezoelectric materials may be used to provide the mechanical actuation causing the adjustment of the geometry.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to an optical element comprising: a first piezoelectric layer of fluorinated polymer with a piezoelectric coefficient, d31, of at least 25 pC/N; an electrode layer disposed on the first piezoelectric layer, wherein an optical characteristic of the optical element changes when the first piezoelectric layer is deformed upon application of a voltage at the electrode layer.

In general, in one aspect, embodiments relate to a piezoelectric optical system comprising: an optical element, comprising: a first piezoelectric layer of fluorinated polymer with a piezoelectric coefficient, d31, of at least 25 pC/N; an electrode layer disposed on the first piezoelectric layer, wherein an optical characteristic of the optical system changes when the first piezoelectric layer is deformed upon application of a voltage at the electrode layer.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1A shows a scenario of a viewer observing visual stimuli under natural viewing conditions.

FIG. 1B shows a scenario of a viewer observing visual stimuli in a fixed focusing distance virtual reality system.

FIG. 1C shows a scenario of a viewer observing visual stimuli in an adjustable focusing distance virtual reality system, in accordance with one or more embodiments.

FIGS. 2A, 2B, and 2C show optical elements in accordance with one or more embodiments.

FIGS. 3A, 3B, and 3C show stack-ups for optical elements in accordance with one or more embodiments.

FIGS. 4A, 4B, and 4C show electrode patterns in accordance with one or more embodiments.

FIGS. 5A-5M show simulations in accordance with one or more embodiments.

FIG. 6 shows an optical system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include piezoelectric optical systems and piezoelectric optical elements. A piezoelectric optical system in accordance with embodiments of the disclosure includes as least one optical element with an adjustable geometry. The optical element may be a lens or a mirror and may include non-rigid elements such as elastic solids, fluids, gases, etc., capable of deformation. The mechanical actuation causing the adjustment of the geometry may be provided by an actuator. In one or more embodiments, the actuator is based on a piezoelectric material that changes shape when electrically driven.

Piezoelectric optical systems equipped with one or more piezoelectrically adjustable optical elements may be optical system of any type and for any application, e.g., projection systems for virtual reality (VR), augmented reality (AR), or mixed reality (MR) applications of any form factor such as head-mounted or stationary. Other application include, but are not limited to cameras, video cameras, microscopes, optical medical devices, and vision correction devices.

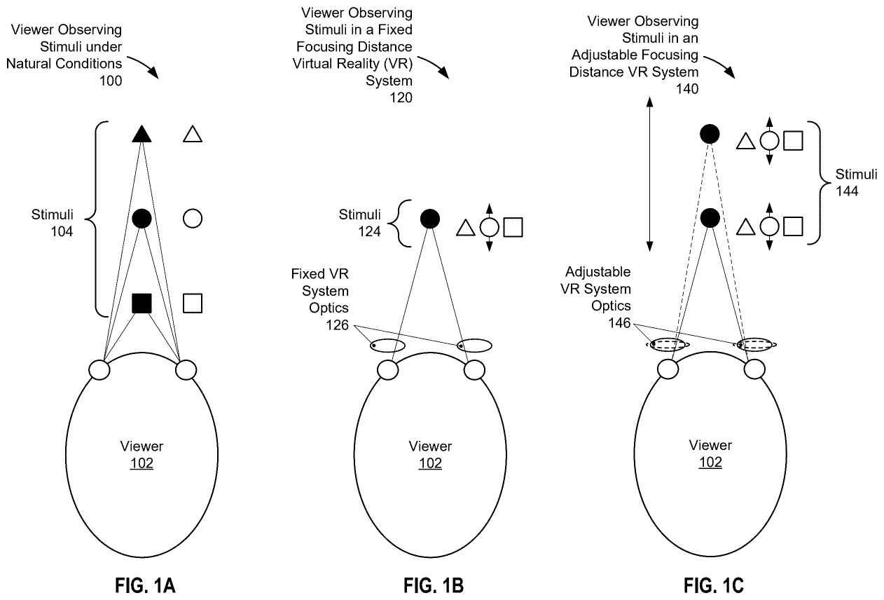

FIGS. 1A, 1B, and 1C provide introductory examples of scenarios involving a viewer observing visual stimuli. Based on these examples, one possible application of optical elements in accordance with embodiments of the disclosure is illustrated.

Turning to FIG. 1A, a first scenario (100) includes a viewer (102) observing stimuli (104) under natural stereoscopic viewing conditions. For example, the viewer (102) may look at objects in the surrounding environment. A stimulus (104) may be a physical object, e.g. a cup on a table, in front of the viewer (102). Three different stimuli (104) are shown at different distances from the viewer (102). The stimuli (104) are represented by different symbols (a rectangle, a circle, and a triangle). The stimuli are shown for accommodation (filled symbols) and vergence (non-filled symbols). Accommodation is the process by which the eye changes optical power to maintain a clear image or focus on an object as its distance varies. Vergence is the simultaneous movement of the pupils of the eyes toward or away from one another during focusing. Under natural viewing conditions, as shown in FIG. 1A, vergence occurs along with accommodation as indicated by the symbols for vergence being aligned with the symbols for accommodation. A physiological control system coordinates vergence and accommodation to jointly occur when viewing objects at different distances (e.g., the three stimuli shown in FIG. 1A.

Turning to FIG. 1B, a second scenario (120) includes a viewer (102) observing stimuli (124) in a stereoscopic virtual reality (VR) environment. Accordingly, the stimuli (124) are virtual objects rather than physical objects. The stimuli (124) may be projected by VR system optics (126). The VR system optics (126) may include various optical elements such as projectors, lenses, mirrors, etc. Many different configurations of VR system optics exist, and any configuration may be used. The VR system optics (126) are fixed VR system optics that establish a focusing distance that does not dynamically change. As a result, in order to obtain a focused view of the stimuli (124), the visual system of the viewer (102) is required to accommodate to a plane at a fixed distance away form the user, indicated by the filled circle symbol. The fixed VR system optics (126) may, however, modulate the depth of the virtual objects (as indicated by the arrow associated with the non-filled symbols, thereby modulating vergence to provide a stereoscopic 3-dimensional cue. A vergence-accommodation conflict may occur when the viewer (102) receives mismatching cues between the distance of a virtual 3D stimulus (vergence), and the focusing distance (accommodation) required for the eyes to focus on that stimulus, i.e. when the depth of the virtual object is in front of or behind the fixed plane dictated by the fixed VR system optics (126). The result may be visual focusing problems, visual fatigue, and eyestrain, while looking at stereoscopic imagery, and vision effects that linger even after ceasing looking at the imagery.

The vergence-accommodation conflict may be particularly severe for stimuli in close proximity to the viewer and occurs because the visual system relies on an accommodation-vergence reflex, which provides coordination between the eyes' optical focus (accommodation) based on the perceived distance to the objects (vergence) that they are looking at.

Turning to FIG. 1C, a third scenario (140) includes a viewer (102) observing stimuli (144) in a stereoscopic virtual reality (VR) environment, in accordance with one or more embodiments. Analogous to the scenario (120) of FIG. 1B, the stimuli (144) are virtual objects rather than physical objects. The stimuli (144) may be projected by VR system optics (146). The VR system optics may include various elements such as projectors, lenses, mirrors, etc. In one or more embodiments, the VR system optics (146) are adjustable VR system optics that are not limited to a fixed focusing distance, unlike the VR system optics (126) of FIG. 1B. Accordingly, a vergence-accommodation conflict may be avoided by adjusting the focusing distance, e.g., along with the depth of the virtual object being displayed or based on other cues such as the current focusing depth of the eyes, if available.

Optical elements in accordance with embodiments of the disclosure, as subsequently described, may be used for the adjustable VR system optics (146).

The application of optical elements in accordance with embodiments of the disclosure is not intended to be limited by the scenario of FIG. 1C. While the scenario of FIG. 1C is used to illustrate unique benefits associated with embodiments of the disclosure, there are various other benefits. Benefits may differ, depending on the application. A detailed description is subsequently provided.

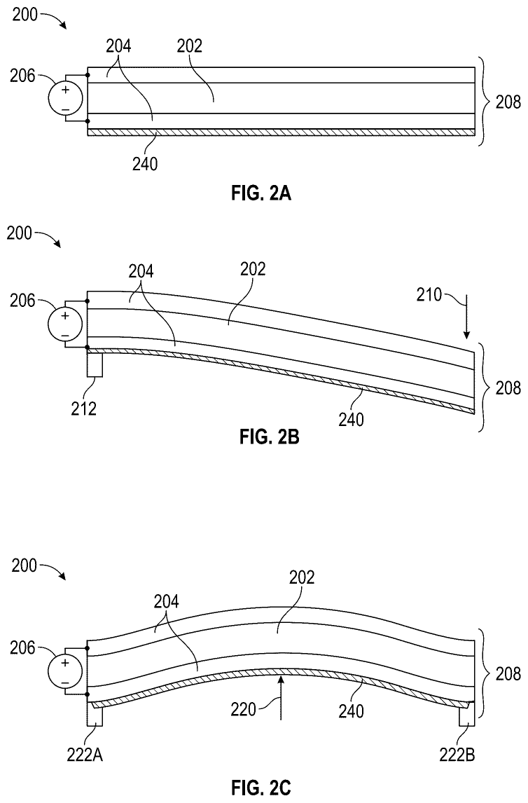

FIGS. 2A, 2B, and 2C show optical elements in accordance with one or more embodiments. While FIGS. 2A, 2B, and 2C introduce optical elements on a conceptual level, showing a minimum of components, actual implementations of optical elements are presented in reference to subsequently described figures.

Two basic groups of optical elements exist: transmissive optical elements (e.g., lenses and prisms) and reflective optical elements (e.g., mirrors). Optical elements may also be partially transmissive and/or partially reflective.

An optical lens is a transmissive optical element which focuses or disperses a light beam by means of refraction. A simple lens consists of a single piece of transparent material, while a compound lens consists of several simple lenses (elements), usually arranged along a common axis. Lenses are made from materials such as glass or plastic, and are ground and polished or molded to a desired shape. A lens can focus light to form an image, unlike a prism, which refracts light without focusing. The optical characteristics of a lens are determined by multiple factors, including the refractive index of the lens material, the curvatures of the two lens surfaces, the thickness of the lens, etc. In addition, different optical characteristics may be obtained based on the positioning of the lens on an optical path (e.g., in an adjustable zoom lens arrangement consisting of a multiple lenses).

An optical mirror is a reflective optical element that reflects light. Metals like silver or aluminum may be used for the reflective surface of the mirror. Non-planar mirrors, i.e., curved mirrors, including concave and convex mirrors may provide diverging and converging optical characteristics, similar to optical lenses. Altering the curvature and or the position of the optical mirror may change the optical characteristics of the optical mirror.

Optical elements such as lenses and mirrors may be designed for the visual spectrum of light and/or for any other wavelength, including the nonvisible spectrum, microwaves, etc.

Optical elements in accordance with embodiments of the disclosure such as lenses and mirrors may be used for many different applications such as display technology including virtual reality and augmented reality displays, stationary or wearable, imaging devices, etc.

Optical elements in accordance with embodiments of the disclosure are deformable in a controllable manner, thereby providing adjustable optical characteristics. Examples of adjustable optical characteristics include adjustments of focal length, but also other adjustments to correct wavefront aberrations such as those associated with myopia, hyperopia, astigmatism, and higher order wavefront aberrations. FIGS. 2A, 2B, and 2C provide a basic description of the components involved in the deformability of the optical elements. Additional components and configurations are described in reference to other figures.

Turning to FIG. 2A, an optical element (200), in accordance with one or more embodiments, is shown. In one or more embodiments, the optical element (200) has multiple layers including a piezoelectric layer (202) and adjacent electrode layers (204). These layers are disposed on a substrate (240). Additional layers may be included, without departing from the disclosure. The function of these layers is subsequently described. In case of a transmissive optical element, the piezoelectric layer (202), the electrode layers (204), and the substrate (240) may have a minimum required transparency. In case of a reflective optical element, the piezoelectric layer (202), the electrode layers (204), and the substrate (240) do not necessarily have a minimum required transparency.

In one or more embodiments, the electrode layers (204) and the piezoelectric layer (202) are arranged in a sandwich architecture where the piezoelectric material is in-between two layers of electrodes. Due to the piezoelectric effect associated with the piezoelectric material, when a voltage is applied to the piezoelectric layer (204), e.g., by a voltage source (206), the charge balance across the piezoelectric layer (204) changes. The change in charge balance may result in deformation of the piezoelectric layer (e.g., as illustrated in FIGS. 2B and 2C). In one embodiment, the piezoelectric layer is a polyvinylidene fluoride (PVDF) piezoelectric film. Piezoelectric materials that are used include, but are not limited to PVDF homopolymers, copolymers (e.g., Poly(vinylidene fluoride-co-trifluoroethylene) (P(VDF-TrFE) co-polymers), Poly(vinylidene fluoride-co-chlorofluoroethylene) (P(VDF-CFE) co-polymers), Poly(vinylidene fluoride-co-chlorotrifluoroethylen) (P(VDF-CTFE) co-polymers), Poly(vinylidene fluoride-co-hexafluoropropylene) (P(VDF-HFP) co-polymers), Poly(vinylidene fluoride-co-tetrafluoroethylene) (P(VDF-TFE) co-polymers), P(VDF-TrFE-CFE) ter-polymers, P(VDF-TrFE-CTFE) ter-polymers), P(VDF-TFE-HFP) ter-polymers, P(VDF-TFE-CTFE) ter-polymers, P(VDF-TFE-CFE) ter-polymers, polylactic acid piezo-biopolymers, polyureas, polyurethanes, polyamides, polyacrylonitriles, a polyimides, polypropylenes, etc. Among these, a film formed from PVDF homopolymer or P(VDF-TFE) copolymer is preferable.

In one or more embodiments, the substrate (240) mechanically supports the sandwich architecture of the piezoelectric layer (202) between the two layers of electrodes (204). The mechanical characteristics of the substrate (240) may affect the deformation of the optical element (200). Accordingly, the choice of the substrate (240) and/or the geometry of the substrate may be a design parameter of the optical element (200). For example, a stiffer substrate may result in less deformation of the optical element in response to the application of a voltage to the piezoelectric layer (204), whereas a less stiff substrate may result in more deformation. In one or more embodiments, the substrate may include or form a deformable optical layer or deformable optical medium as further described below, e.g., in the form of a lens, where the stiffness may be selected to achieve a desired deformation of the sandwich like structure that includes the piezoelectric layer(s) and the optical layer.

Additional layers may be added to the piezoelectric film. The additional layers may include one or more of, for example, a hard coat layer, an index matching layer, an antistatic layer, etc. A description of a piezoelectric film is provided in PCT Patent Application No. PCT/JP2021/013199. PCT/JP2021/013199 is hereby incorporated by reference in its entirety.

The piezoelectric film may be manufactured using an extrusion, solvent casting, or heat press process. The polarization responsible for the piezoelectric behavior of the piezoelectric film may be obtained by stretching and/or exposure to a high electric field, which may be performed separately or simultaneously. Stretching may be performed uniaxially or biaxially. A description of the manufacturing process is provided in U.S. Pat. No. 8,356,393. U.S. Pat. No. 8,356,393 is hereby incorporated by reference in its entirety.

In one or more embodiments, the piezoelectric layer (204) is based on a piezoelectric film polarized by exposure to a high electric field during the manufacturing of the piezoelectric film, without requiring mechanical stretching that would otherwise be used to obtain the polarization. The electric field strength during the polarization treatment may be 200 to 600 MV/m and the polarized polymer includes a polar α-type crystal structure. The resulting piezoelectric film is less prone to shrinkage, flexing and/or peeling when laminated with an electrode layer. A description of a piezoelectric film manufactured in this manner is provided in Japanese Pre-Grant publication No. JP2011192665A. JP2011192665A is hereby incorporated by reference in its entirety. Alternatively, the piezoelectric film may be directionally oriented through stretching, either uniaxially or biaxially.

The piezoelectric film in accordance with embodiments of the disclosure may have one or more of the following characteristics. The sensitivity (expressed as an electric charge in response to a force being applied, i.e. a piezoelectric coefficient, d₃₁) may be greater than 10 pC/N or greater than 20 pC/N, or at least 25 pC/N. A fluorinated polymer with high d₃₁ may be obtained using different methods: Copolymer/terpolymer or mixed polymers with higher piezoelectric effect may be used; strong polarization treatment may be used; the drawing ratio may be increased; a nucleating agent may be added to increase the amount of beta-crystals, etc. The piezoelectric film may have any thickness, e.g., in a range of 5-200 μm. The thickness of laminated layers may be uniform or layers with different thicknesses may be combined according to the direction of deformation desired. The optical transmittance of the piezoelectric film may be at least 80%, 90%, or 95%. The transmission haze of the piezoelectric film may be less than 10% or less than <5%. The piezoelectric film may have a Young's modulus of at least 1500 MPa. The piezoelectric film may have an electromechanical coupling coefficient, k₃₁, of at least 0.1. The piezoelectric film may have a heat shrinkage rate of 2% or less after exposing the piezoelectric layer to a temperature of 75° C. for 30 min. The piezoelectric film may have a surface roughness (Ra) of 350 nm or less. The piezoelectric film may have a lightness value (L*) of at least 95%, a green-red color component (a*) of less than 0.1, and a blue-yellow component (b*) of less than 0.5. The piezoelectric film may have a Poisson's ratio, v₃₁ in a range between 0.15 and 0.8. The piezoelectric film may include agents such as ammonium salt, polymethyl methacrylate (PMMA), graphene, carbon nanotubes (CNTs), and fullerenes crystal nucleating agents that help to increase the ratio of β-type crystals.

In one or more embodiments, the electrode layers (204) include one or more electrodes either as a uniform layer, or patterned, as discussed below in reference to FIGS. 4A, 4B, and 4C. The electrodes may consist of a transparent conductive coating such as, indium tin oxide (ITO), CNTs, doped CNTs, a mixture of CNTs with metal nanowires (e.g., silver nanowires), conductive polymers (e.g., poly(3,4-ethylendioxythiophene) polystyrene sulfonate or PEDOT:PSS), graphene, metal mesh, etc. Non-transparent materials may be used for the electrodes in applications where transparency is not needed (e.g., when the optical element is a mirror). For example, metal, inorganic oxides, carbon, conductive polymers, etc., may be used.

The electrodes in the electrode layers (204) in accordance with embodiments of the disclosure may have one or more of the following characteristics. The sheet resistance across an electrode layer may be kept low. The sheet resistance may be less than 300 ohm/sq., less than 100 ohm/sq. or less than 50 ohm/sq. The optical transmittance of an electrode layer may be at least 90% or at least 95%. The transmission haze of an electrode layer may be less than 10% or less than <5%.

In one or more embodiments, the combination of the piezoelectric layer (202) and the electrode layers (204) forms a piezoelectric actuator (208). The piezoelectric actuator (208) produces a mechanical output, e.g., motion, in presence of an electric input, e.g., a voltage.

In one or more embodiments, the combination of the piezoelectric layer (202) and the electrode layers (204) forms a piezoelectric stripe actuator, also called a bending actuator. The stripe actuator may be designed to produce a relatively large mechanical deflection in response to the application of a voltage. The stripe actuator may include two piezoelectric layers that are bonded together. The two piezoelectric layers are arranged such that when a voltage is applied, one piezoelectric layer expands whereas the other piezoelectric layer contracts or does not change length, thereby causing a flexion, as illustrated in FIGS. 2B and 2C.

While not shown, piezoelectric actuators in accordance with embodiments may deform in other ways. For example, a piezoelectric actuator may lengthen or shorten, buckle or twist, in one or more directions.

In one or more embodiments, the piezoelectric actuator (208) provides an actuation that alters one or more optical characteristics of the optical element (200). The change in optical characteristics may be a result of a deformation of the elements shown in FIG. 2. For example, if the piezoelectric layer (202) and the electrode layers (204) are substantially transparent, they may form a tunable lens. Alternatively, additional components may be involved in the change in optical characteristics. For example, the addition of an optically reflective layer may provide a tunable mirror. Other combinations of elements are described below. Many different types of tunable optical elements including, but not limited to active gratings, tunable lenses, and tunable mirrors may be formed in this manner.

Turning to FIG. 2B, the optical element (200) of FIG. 2A is shown. Unlike in FIG. 2A, where the voltage source (206) is inactive (no voltage across the electrodes in the electrode layers), in FIG. 2B, the voltage source (206) is active.

In FIG. 2B, the optical element (200) is unilaterally anchored by an anchor (212). Accordingly, application of a voltage via electrodes in the electrode layers (204) results in a deformation (210) of the optical element (200). In FIG. 2B, the deformation includes a flexing of the optical element (200) resulting in a displacement of a free end of the optical element (200). As a result of the deformation (210), the optical characteristics of the optical element (200) may change. For example, the change in curvature along the optical element (200) as a result of the flexing of the optical element may result in a change of the optical characteristics. Further, the translational offset at the free end of the optical element may also result in a change of the optical characteristics.

Turning to FIG. 2C, the optical element (200) of FIG. 2A is shown. Unlike in FIG. 2A, where the voltage source (206) is inactive (no voltage across the electrodes in the electrode layers), in FIG. 2C, the voltage source (206) is active.

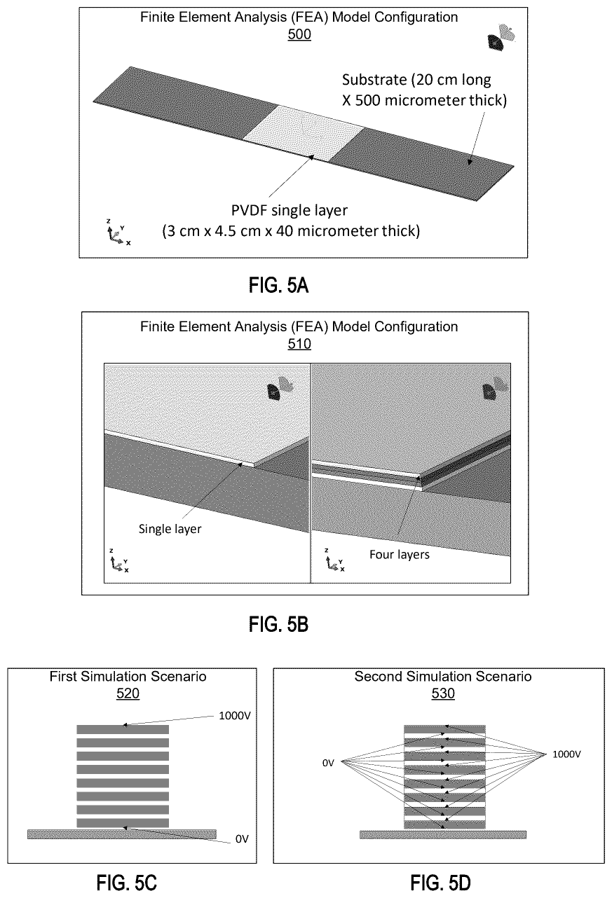

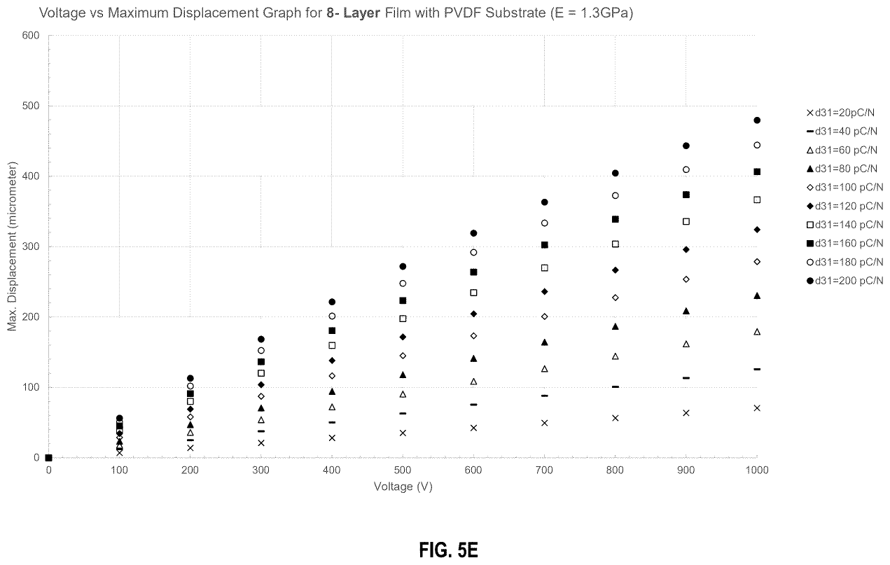

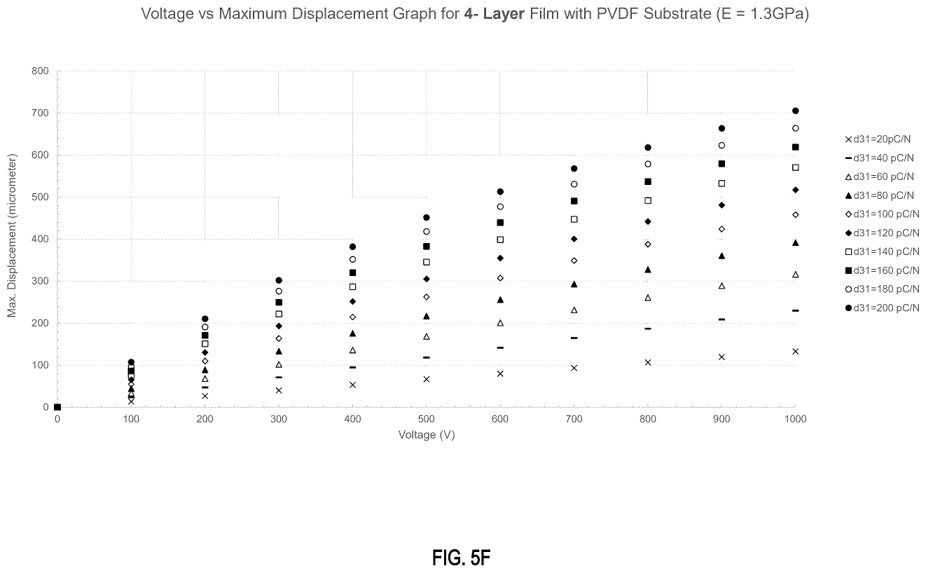

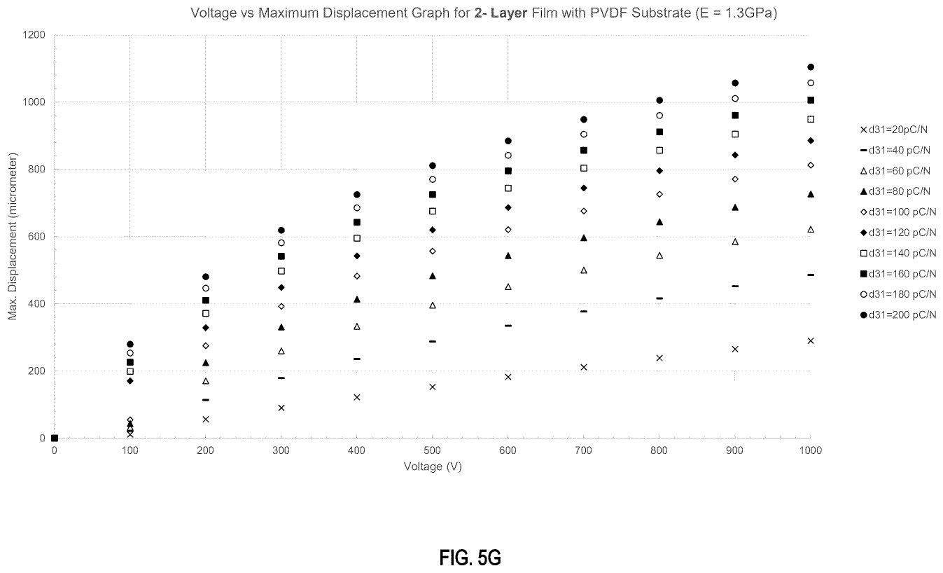

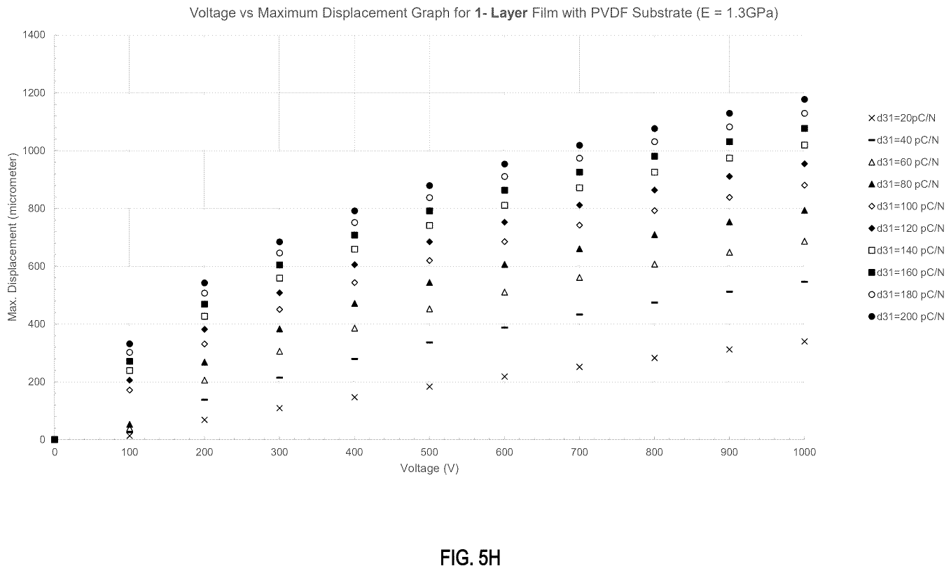

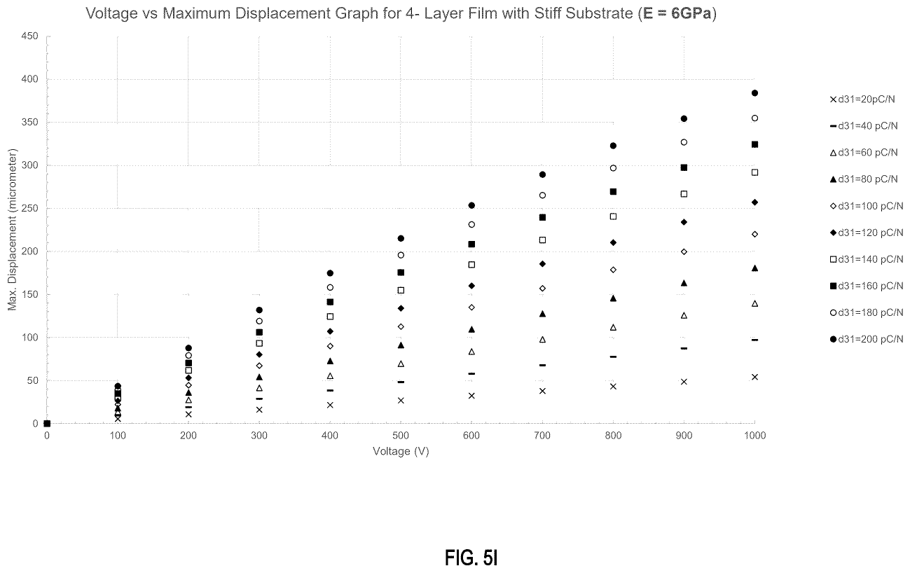

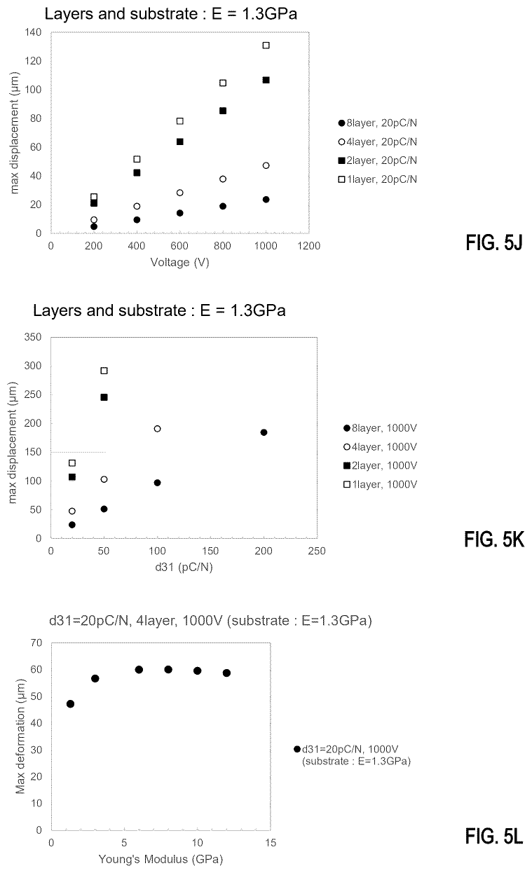

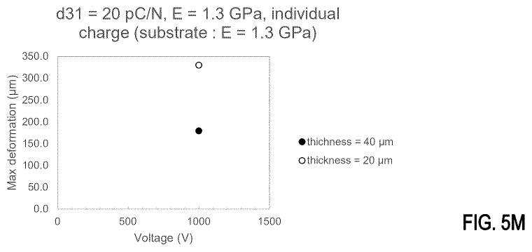

In FIG. 2C, the optical element (200) is bilaterally anchored by anchors (222A, 222B). Accordingly, application of a voltage via electrodes in the electrode layers (204) results in a deformation (220) of the piezoelectric element (200) in a central region. In FIG. 2C, the deformation includes a flexing or buckling of the piezoelectric element (200). As a result of the deformation (220), the optical characteristics of the optical element (200) may change. For example, the change in curvature along the optical element (200) as a result of the flexing of the optical element may result in a change of the optical characteristics. Simulation results for an optical element as shown in FIG. 2C are summarized below in reference to FIGS. 5A-M.

While FIGS. 2B and 2C show discrete rigid anchors (212, 222A, 222B), other types of anchors may be used without departing from the disclosure. For example, an anchor may be flexible rather than rigid. Materials such as a polymer, gel, foam, gas, and/or liquid may be used. Further, an anchor may span part or all of a surface of the optical element (200).

The deformations (210, 220) shown in FIGS. 2B and 2C may be graded. A higher voltage by the voltage source (206) may result in a more significant deformation. A voltage reversal may result in a deformation in the opposite direction. Depending on the design of the optical element (200), the voltage provided by the voltage source may reach different values, e.g., up to 10V, up to +/−10V, up to 2,000V, up to +/−2,000V or any voltage in between. When applying voltages to the optical element (laminated layers), the voltages may be applied in series or in parallel or to individual layers. When applying voltages individually, the same voltage may be applied to each layer, or different voltages may be applied depending on the shape to be deformed. To achieve the desired amount of deformation, an optical element may be driven with a voltage of 50V or more to each layer. Although a higher voltage may sufficiently deform the piezoelectric optical elements, it may be preferable to drive at a lower voltage in terms of power consumption. Because the piezoelectric coefficient d₃₁ has a large effect on the amount of the deformation, in order to obtain enough deformation while keeping the voltage low, the driving conditions may be selected based on a combination of a voltage and d₃₁. In one or more embodiments, the product of the absolute value of d₃₁ (pC/N) and the voltage (V) applied to each piezoelectric layer is 4,000 or more (pC/N*V). Different electrode patterns, described below in reference to FIGS. 4A-4C, may further be used to precisely control the deformation of the optical element.

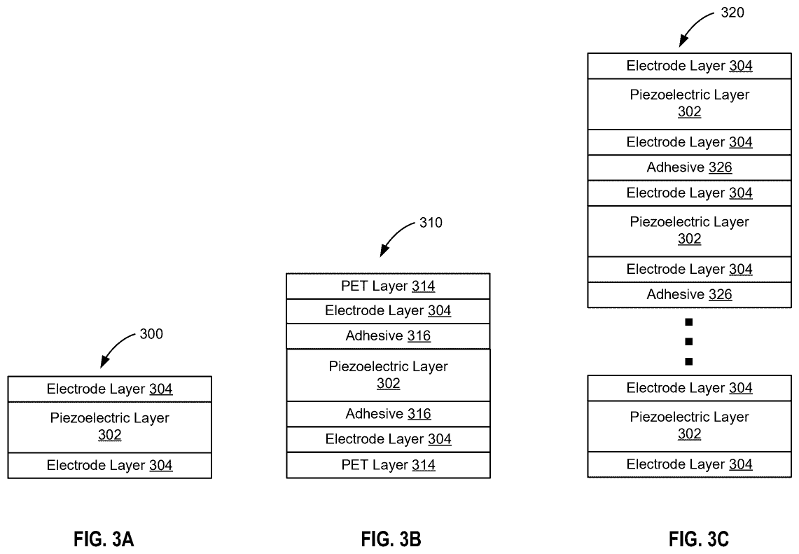

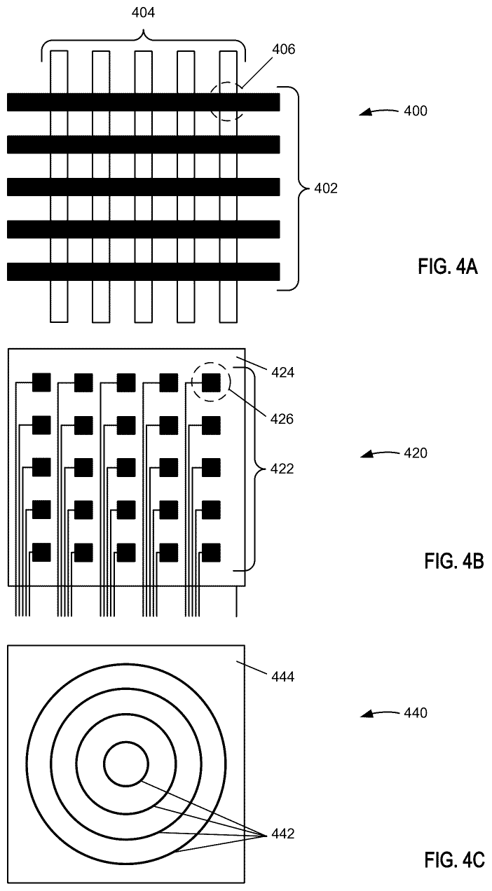

FIGS. 3A, 3B, and 3C show stack-ups for optical elements in accordance with one or more embodiments. The stack-ups of FIGS. 3A-3C illustrate how the previously described layers may be arranged, and further how additional layers may be included in the stack-up.

Referring to FIG. 3A, the stack-up (300) includes a piezoelectric layer (302), and two electrode layers (304) similar to what is shown in FIGS. 2A-2C.

Referring to FIG. 3B, the stack-up (310) includes the elements of the stack-up (300) of FIG. 3A and, in addition, polyethylene terephthalate (PET) layers (314) and adhesive layers (316). The PET layers (314) may be used to facilitate the manufacturing of the optical element. Specifically, the electrodes in the electrode layers (304) may be disposed on the PET layers (314) instead of being disposed on the piezoelectric layer (302). The adhesive (316) may permanently bond the PET layers (314) with the electrodes to the piezoelectric layer (302). The stack-up (310) may otherwise be similar to the stack-up (300).

Referring to FIG. 3C, the stack-up (320) includes multiple arrangements of the layers of the stack-up (300). Any number of the stack-ups (300) may be stacked. An adhesive (326) may mechanically link the individual stack-ups. The stacking as shown in FIG. 3C may increase the motion amplitude that is produced, where the overall motion amplitude may be the sum of the displacement of each piezoelectric layer. The stacking may further enable more complex motion patterns involving any combination of compression, extension, twisting, and bending.

The piezoelectric layers in the stack-up (320) may be uniaxially oriented, each in a unique direction. Accordingly, each of the piezoelectric layers may have a unique, directional deformation pattern such as the bending described in reference to FIGS. 2B and 2C. While the deformation of individual piezoelectric layers may be anisotropic (e.g., as shown in FIG. 2B), the combination of multiple piezoelectric layers may result in an isotropic deformation. For example, the resulting deformation may be symmetric to a rotation axis. Such a deformation pattern may be particularly beneficial for frequently circular-shaped lenses, mirrors, etc. To create symmetrical concentric deformation in a rectangular element, four or more layers with different orientations may be used.

While FIGS. 3A-3C show various stack-ups, other stack-ups may be implemented without departing from the disclosure. For example, any component shown in one of the stack-ups may also be present in any of the other stack-ups. Also, while the stack-ups of FIGS. 3A-3C show all layers as flat, a stack-up may alternatively be pre-tensioned, e.g., having curvature or any other deviation from substantially flat. Pre-tensioning may be accomplished during the lamination process of the layers. Stack-ups may further include layers of a single fluorinated polymer, multiple different fluorinated polymers, and/or multiple different fluorinated polymer blends. Fluorinated polymer layers with different properties (such as d₃₁, mechanical properties, thickness, and so on) may be laminated or the same fluorinated polymer layers may be laminated. Examples of fluorinated polymers and other electroactive materials that may be stacked include ceramic materials such as K0.5 Na0.5 NbO3 (“KNN”), barium titanate, lithium niobate, lithium tetraborate, quartz, Pb(Mg1/3Nb2/3)3-PbTiO3 (“PMN-PT”), Pb(Zn1/3Nb2/3)O3-PbTiO3 (“PZN-PT”), and zirconate titanate (“PZT”), other piezoelectric polymers such as polylactic acid piezo-biopolymer, polyurea, polyurethane, polyamide, polyacrylonitrile film, polyimide, and polypropylene, and/or other electroactive polymers such as dielectric electroactive polymer, ferroelectric polymer, electrostrictive polymer, ionic electroactive polymer, and stimuli-responsive gel.

The selection of a particular stack-up may be based on various considerations. For example, more basic stack-ups (fewer layers) may be more cost effective and/or more compact. Other stack-ups may be easier to manufacture. For example, additional PET layers may be used to support the electrodes instead of directly having the electrodes on the surfaces of the piezoelectric film. Further, certain stack-ups may be more suitable to accomplish specific types of deformations required by or desired for a particular optical application. Specific types of deformations may also be obtained by selectively driving the piezoelectric layer(s) using patterned electrodes.

FIGS. 4A, 4B, and 4C show electrode patterns in accordance with one or more embodiments. Electrode patterns may be used to selectively expose a limited region of a piezoelectric layer to a voltage. A basic electrode pattern may involve two electrodes, one on either side of the piezoelectric layer. With this electrode pattern, the entire piezoelectric layer may be driven at once and non-discriminately. The following description refers to electrode patterns that allow for a selective driving of the piezoelectric layer. Some piezoelectric implementations utilize arrays or other regular or irregular patterns of electrodes to drive the piezoelectric material at different locations across the piezoelectric layer.

Turning to FIG. 4A, a first electrode pattern (400), in accordance with one or more embodiments, is shown. The electrode pattern includes rows of first electrodes (402) and columns of second electrodes (404). The first electrodes (402) may be located in one of the two electrode layers (204) of the optical element (200) of FIGS. 2A-2C. Likewise, the second electrodes (404) may be located in the other of the two electrode layers (204). In the electrode pattern (400), the first electrodes (402) and the second electrodes (404) have rectangular shapes. The electrodes may have different shapes, without departing from the disclosure. For example, interconnected diamond-shaped electrode pads may be arranged in rows or columns. While not shown, the piezoelectric layer (202) may be located between the first electrodes (402) disposed on one surface of the piezoelectric layer and the second electrodes (404) disposed on the other surface of the piezoelectric layer, as previously discussed.

At the intersection of a first electrode (402) and a second electrode (404), a voltage may be applied to the piezoelectric layer in a localized manner. The region of this localized driving of the piezoelectric layer may be termed a “driving element” (406). While only a single driving element (406) is identified in FIG. 4A, a driving element (406) may exist at each intersection of a first electrode (402) and a second electrode (404). By applying a voltage at each of the driving elements (406), the behavior (e.g., deformation) of the piezoelectric layer may, thus, be locally controlled across the entire (or part of) the piezoelectric layer. The application of a voltage may be performed in a scanning operation, e.g. row-by-row and/or column-by-column until all driving elements (406) have been driven. Different voltages may be applied at different driving elements (406) to obtain the desired mechanical behavior of the piezoelectric layer. If the driving of the different driving elements is performed at a sufficiently high frequency over time, a quasi-static mechanical behavior of the piezoelectric layer may be obtained. The driving operations may be performed by a driving circuit (not shown). The driving circuit may drive each of the driving elements with the voltage specific to the driving element.

While the electrode pattern (400) is for a substantially rectangular area, the electrode pattern may be altered to have a different geometry. For example, the outline of the electrode pattern (400) may be circular.

Turning to FIG. 4B, an electrode pattern (420) is shown. The electrode pattern includes a pattern of first electrodes (422) and a single second electrode (424) spanning the region of the first electrodes (422). The first electrodes (422) may be located in one of the two electrode layers (204) of the optical element (200) of FIGS. 2A-2C. Likewise, the second electrode (424) may be located in the other of the two electrode layers (204). In the electrode pattern (420), each of the first electrodes (422) is a pad which may have any shape.

A driving element (426) is formed at each of the first electrodes (422). While the design of the electrode pattern (420) is different from the design of the electrode pattern (400), the driving of the piezoelectric layer with voltages may be performed in a similar manner.

While FIGS. 4A and 4B show two types of electrode patterns, other types of electrode patterns may be used without departing from the disclosure. Also, non-patterned electrodes (e.g., solid-surface electrodes) may be used. Further, electrode patterns may be scaled in size and/or resolution, without departing from the disclosure.

Turning to FIG. 4C, a third electrode pattern (440), in accordance with one or more embodiments, is shown. The third electrode pattern may be particularly suitable to produce non-uniform deformations for lenses and other optical elements. For example, the third electrode pattern (440) may be used to provide the curvature, bending, and combined curvature and bending deformations shown in FIG. 2C, although in an axisymmetric manner. As shown in FIG. 4C, an axisymmetric electrode pattern (440) may be used to induce an axisymmetric or nearly axisymmetric deformation. In the example, the first electrodes are ring-shaped, whereas the second electrode is non-patterned. The axisymmetric nature of the electrode pattern may create a nearly axisymmetric curvature change to adjust optical power. Any number of ring-shaped first electrode may be used. While a fully axisymmetric implementation is shown in FIG. 4C, other implementations may not necessarily be fully axisymmetric. For example, the electrode pattern (440) may include one or more first electrodes that are not circular. While FIG. 4C shows a single second electrode (444), in other embodiments a set of second electrodes may be arranged in a pattern, e.g., as radially oriented spokes, or in other patterns. Patterned second electrodes may enable correction of optical aberrations by deviating from a strictly axisymmetric deformation of the optical element.

Based on the introduction of optical elements, stack-ups, and electrode patterns, additional configurations of optical elements are subsequently described.

In one embodiment, an optical element includes a sandwich structure of multiple optical layers and multiple piezoelectric layers. The optical element may include, from bottom to top, an optical layer, two or more piezoelectric layers, and another optical layer. The piezoelectric layers may be jointly or individually driven using electrode layers that may be patterned to cause the desired deformation of the optical element.

In one embodiment, a Fresnel lens may be integrated with an optical element, such as an optical element having a bimorph architecture. For example, the optical element may include one or more piezoelectric layers and a Fresnel lens in a sandwich-like structure. The piezoelectric layers may be jointly or individually driven using electrode layers that may be patterned to cause the desired deformation of the Fresnel lens. The deformation may change the optical characteristics of the Fresnel lens. For example, the deformation may, in extension, vary the pitch within an active grating or, in bending, change curvature to vary optical power, selectively reflect or refract light, and/or provide beam steering.

Other embodiments may include deformable optical media such as a gas (e.g., air, nitrogen, etc.), a liquid (e.g., water, saline solution, a high-refractive index liquid, etc.), a polymer material, a gel (e.g., a silicone gel), a foam (e.g., a silica aerogel), etc.

While various different optical elements have been described, many other combinations may be used without departing from the disclosure. Additional examples include the combination of Fresnel lenses or pancake lenses with piezoelectric actuators. In one embodiment, one or more piezoelectric actuators are combined with a pancake lens. The resulting pancake lens assembly may be used in an optical system to fold the optical path from a light source to a detector. For example, the pancake lens assembly may be used in a head-mounted display (HMD), to fold the optical path, thereby reducing the back focal distance in the HMD. The pancake lens assembly may include a first optical element, a piezoelectric actuator (a varifocal lens), and a second optical element. The first optical element and the second optical element may form a cavity, and the varifocal lens may be disposed inside or outside the cavity. In one embodiment, one or more piezoelectric actuators are combined with an Alvarez lens. The piezoelectric actuator(s) may drive the lateral displacement of the two lens elements of the Alvarez lens against each other to make focusing or de-focusing adjustments.

Regardless of the particular embodiment under consideration, the use of piezoelectric actuators may provide various benefits. For example, PVDF (and similar materials) is flexible, hence resistant to repeated deformations, and provide a fast response time and wide frequency response. Further, the properties of the PVDF (and similar materials) may be controlled by making adjustments to the manufacturing process, copolymerization, and/or by mixing with other polymers or other materials. Optical elements in accordance with embodiments of the disclosure may be suitable for many applications, having specifiable characteristics. For example, the characteristics of an optical element may include an achievable deformation of at least 200 μm, a capability to correct 2^{nd} or higher order wavefront aberrations, an adjustable focal length ranging from 10 cm to ∞, etc.

Also, while FIGS. 2A-2C, 3A-3C, and 4A-4C show configurations of components, other configurations may be used without departing from the scope of the disclosure. For example, various components may be combined to create a single component. As another example, the functionality performed by a single component may be performed by two or more components.

FIGS. 5A-5M show simulations in accordance with one or more embodiments.

Turning to FIG. 5A, a finite element analysis (FEA) model configuration, in accordance with one or more embodiments, is shown. The FEA model configuration (500) is used for the subsequently described simulations. The FEA model configuration (500) includes a rectangular (3 cm×4.5 cm) piezoelectric based lens comprising a piezoelectric layer having a thickness of 40 micrometers, a Poisson's ratio of 0.3 and a density of 1.78 g/cm³. Another FEA model configuration (not shown) includes a circular (3 cm diameter) piezoelectric based lens comprising a piezoelectric layer having a thickness of 40 micrometers, a Poisson's ratio of 0.3 and a density of 1.78 g/cm³. In some configuration, the piezoelectric layer of the circular lens has a thickness of 20 micrometers.

Turning to FIG. 5B, two FEA model configurations, in accordance with one or more embodiments, are shown. A first of the FEA model configurations (510) includes a single piezoelectric layer (left), and a second of the FEA model configurations (510) includes four piezoelectric layers (right). Two additional FEA model configurations (now shown) include two and eight piezoelectric layers. For the simulation, each of the two, four and eight layers may be connected using tie constraints (representing, e.g., bonding or gluing in an actual implementation).

An FEA of the optical element deformation under different conditions was performed. Parameters there were varied included d₃₁, the Young's modulus, the voltage, the number of layers, and the layer thickness.

In a first simulation scenario (520), shown in FIG. 5C as for the eight layers, a voltage was applied across the entire stack of layers. The layers in the stack are in direct contact, and the stack may have any number of layers. The following results were obtained: (1) With increasing voltage and increasing d₃₁ values, the maximum deformation and curvature of the stack-up increased. (2) When a constant voltage was applied to the entire stack-up, the resistance to deformation increased when the number of layers was increased. (3) As the Young's modulus of the layer(s) was increased, the displacement increased until an optimum value for the Young's modulus was reached. Beyond the optimum value, no further continuous increase in the displacement was observed. In direct comparison, d₃₁ was found to have a larger effect on deformation than Young's modulus. Also, the smaller the young's modulus of the substrate (anchor) in contact with the bottom surface, the larger the deformation. In a second simulation scenario (530), shown in FIG. 5D, a voltage was applied to individual layers (potential difference of 1000 V across each layer). In this configuration, a thin (e.g., 1 μm) insulation layer may separate the stacked layers. The insulation layer may have a stiffness similar to the stiffness of the layers. The increased voltage resulted in a larger deformation and curvature of the layers. Also, the rectangular lens provided a larger deformation than the circular lens, assuming the same material properties and electric charging. In contrast, the circular lens in a configuration with fewer layers, achieved a smoother and more uniform curvature than the rectangular lens. In the simulations, a thinner lens produced larger deformations than a thicker lens, with no negative effect on the smoothness of the lens curvature. It was further determined that at least four layers may be needed to create a symmetrical circular deformation in a rectangular optical element.

FIGS. 5E-5I show simulation results in accordance with embodiments of the disclosure. The simulation results are for the first simulation scenario, using a rectangular model. Displacements in response to different voltages are shown for different configurations such as 8-layer, 4-layer, 2-layer, and 1-layer configurations including the layer having 40 micrometers in thickness with PVDF and stiff substrates. The simulation results are for a number of different d₃₁ values. Further, FIGS. 5J-5L show additional simulation results in accordance with embodiments of the disclosure, for the first simulation scenario and using a circular model. FIG. 5M shows additional simulation results in accordance with embodiments of the disclosure, for the second simulation scenario and using a circular model. Displacements in response to 1000V are shown for 8-layer configurations including the piezoelectric layer having either 40 micrometer or 20 micrometer in thickness and the thin insulation layer having 1 micrometer in thickness.

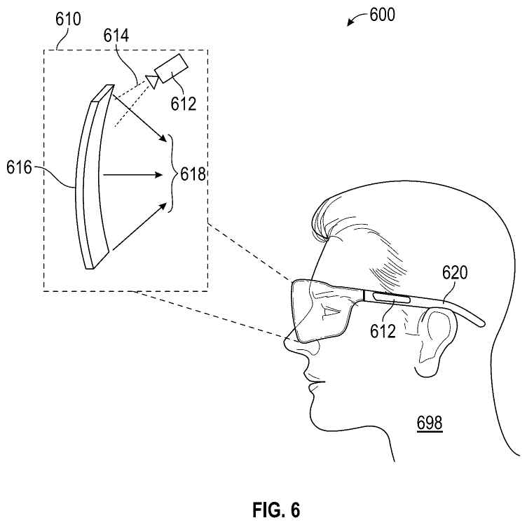

Turning to FIG. 6, an optical system in accordance with one or more embodiments is shown. The optical system (600) in FIG. 6 is a head-mounted display (HMD), either in the form of glasses or in a more immersive helmet-type configuration. The HMD may include one or more display assemblies (610) in accordance with embodiments of the disclosure. The display assembly (610) may be located within a transparent aperture of the HMD (600) and configured to present media to a user (698). In the example, the display assembly (610) includes a display device, e.g., an image projector (612). The image projector (612) may be mounted on the temple arm (620) of the HMD (600). Projected light (614) may be steered by a beam steerer (not shown), reflected by the combiner (616), and the resulting reflected light (618) may be focused onto the pupil of the user (698). In an AR system, the user would simultaneously view a real object through the at least partially transparent combiner (616). In one or more embodiments, the combiner (616) is or includes an optical element as previously described. For example, the combiner (616) may include a Fresnel combiner or a pancake combiner and may include an optical element as previously described, an ellipsoidal mirror, one or more tunable waveguides, or a holographic combiner. Actuation of the optical element may increase or decrease the focal distance of the HMD and provide eye relief adjustment. The HMD may include additional components. For example, an additional optical element, different from the combiner (616) may be adjustable using a piezoelectric actuator. In some embodiments, HMD or AR glasses are configured to provide augmented reality contents to a wearer of display device. For example, the HMD may include an eye tracker (not shown). The eye tracker may be used to track the user's position of pupil, and focusing distance, thereby enabling a closed loop operation of the AR or VR glasses to avoid a vergence-accommodation conflict. Based on the detected the position of pupil and estimated focusing distance, the focal length of the lens or mirror may be adjusted in x- and/or y-directions, or in the x-, y- and/or z-directions. The adjustment may be performed in real-time. The HMD may also include one or more audio speakers to increase the level of immersion. The audio speakers may be piezoelectric film-based audio speakers. In one embodiment, the audio speakers are bone conduction-based speakers.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. An optical element comprising:
a first piezoelectric layer of fluorinated polymer with a piezoelectric coefficient, d₃₁, of at least 25 pC/N;
an electrode layer disposed on the first piezoelectric layer,
wherein an optical characteristic of the optical element changes when the first piezoelectric layer is deformed upon application of a voltage at the electrode layer.

2. The optical element of claim 1, wherein the fluorinated polymer comprises at least one selected from a group consisting of a polyvinylidene fluoride (PVDF) homopolymer, a Poly(vinylidene fluoride-co-trifluoroethylene) (P(VDF-TrFE) co-polymer), a Poly(vinylidene fluoride-co-chlorofluoroethylene) (P(VDF-CFE) co-polymer), a Poly(vinylidene fluoride-co-chlorotrifluoroethylen) (P(VDF-CTFE) co-polymer), a Poly(vinylidene fluoride-co-hexafluoropropylene) (P(VDF-HFP) co-polymer), a Poly(vinylidene fluoride-co-tetrafluoroethylene) (P(VDF-TFE) co-polymers), a P(VDF-TrFE-CFE) ter-polymer, a P(VDF-TrFE-CTFE) ter-polymer, a P(VDF-TFE-HFP) ter-polymers, a P(VDF-TFE-CTFE) ter-polymers, and a P(VDF-TFE-CFE) ter-polymers.

3. The optical element of claim 1, wherein the first piezoelectric layer is one selected from a group consisting of an uniaxially oriented film, a biaxially oriented film, or an unoriented film.

4. The optical element of claim 1, wherein the first piezoelectric layer has an optical transmittance of at least 80%.

5. The optical element of claim 1, wherein the first piezoelectric layer has a thickness in a range between 5 μm and 200 μm.

6. The optical element of claim 1, wherein the first piezoelectric layer has a Young's modulus of at least 1500 MPa.

7. The optical element of claim 1, wherein the first piezoelectric layer has an electromechanical coupling coefficient, k₃₁, of at least 0.1.

8. The optical element of claim 1, wherein the first piezoelectric layer has a heat shrinkage rate of 2% or less after exposing the piezoelectric layer to a temperature of 75° C. for 30 min.

9. The optical element of claim 1, wherein the first piezoelectric layer has a surface roughness (Ra) of 350 nm or less.

10. The optical element of claim 1, wherein the first piezoelectric layer has a lightness value (L*) of at least 95%, a green-red color component (a*) of less than 0.1, and a blue-yellow component (b*) of less than 0.5.

11. The optical element of claim 1, driven such that the product of the absolute value of d₃₁ (pC/N) and the voltage (V) applied to each piezoelectric layer is 4,000 or more (pC/N*V).

12. The optical element of claim 1, wherein the fluorinated polymer comprises agents selected from at least one of a group consisting of ammonium salt, polymethyl methacrylate (PMMA), graphene, carbon nanotubes (CNTs), and fullerene as crystal nucleating agents.

13. The optical element of claim 1, further comprising:
a hard coat layer deposited onto the first piezoelectric layer.

14. The optical element of claim 1, wherein the electrode layer is one selected from a group consisting of ITO, metal nanowires, metal mesh, CNTs, graphene, and poly(3,4-ethylendioxythiophene) polystyrene sulfonate.

15. The optical element claim 1, wherein the voltage is in a range between 10V and 2,000V.

16. The optical element of claim 1, further comprising:
a second piezoelectric layers of fluorinated polymer.

17. The optical element of claim 16, wherein the first piezoelectric layer and the second piezoelectric layer are stacked in different orientations.

18. The optical element of claim 1, wherein the optical element is one selected from a group consisting of a tunable lens and a tunable mirror.

19. The optical element of claim 18, wherein the tunable lens is one selected from a group consisting of a pancake lens, an Alvarez lens, and a Fresnel lens.

20. The optical element of claim 18, wherein the tunable lens has an adjust focal length in a range between 10 cm and ∞.

21. The optical element of claim 1, wherein the deformation is at least 50 μm.

22. The optical element of claim 1, correcting second or higher order wavefront aberrations.

23. A piezoelectric optical system comprising:
an optical element, comprising:
a first piezoelectric layer of fluorinated polymer with a piezoelectric coefficient, d₃₁, of at least 25 pC/N;
an electrode layer disposed on the first piezoelectric layer,
wherein an optical characteristic of the optical system changes when the first piezoelectric layer is deformed upon application of a voltage at the electrode layer.

24. The piezoelectric optical system of claim 23, wherein the piezoelectric optical system is one selected from a group consisting of a headset and a set of glasses.

25. The piezoelectric optical system of claim 24, further comprising:
an eye tracker determining a current focusing distance of a user using the optical system,
wherein the optical characteristic is adjusted based on the current focusing distance.

26. The piezoelectric optical system of claim 24, further comprising:
a piezoelectric film-based audio speaker.

27. The piezoelectric optical system of claim 23, wherein the optical characteristic is a focal length of the optical element.

28. The piezoelectric optical system of claim 23, wherein the piezoelectric optical system in integrated in one selected from a group consisting of an Augmented Reality (AR) application, a Virtual Reality (VR) application, and a Mixed Reality (MR) application.
